(19) United States
(12) Patent Application Publication
(10) Pub. No.: US 2023/0113869 A1
(43) Pub. Date: Apr. 13, 2023

(54) SUBSTRATE TRANSFER APPARATUS

(71) Applicant: Samsung Electronics., Ltd, Suwon-si (KR)

(72) Inventors: Juno Kim, Suwon-si (KR); Daeho Min, Seoul (KR); Minwoo Rhee, Seoul (KR); Junhyung Kim, Yongin-si (KR); Kyeongbin Lim, Seoul (KR)

(21) Appl. No.: 17/807,660

(22) Filed: Jun. 17, 2022

(30) Foreign Application Priority Data
Oct. 8, 2021 (KR) 10-2021-0134253

(51) Int. Cl. H01L 21/683; H01L 21/68; H01L 21/67

(52) U.S. Cl. CPC H01L 21/6838; H01L 21/681; H01L 21/67144

(57) ABSTRACT

A substrate transfer apparatus includes a plurality of holding units adjacent to a front surface of a substrate. The plurality of holding units includes a plurality of holding surfaces for holding the substrate without contact. A plurality of vacuum holes is disposed in the plurality of holding surfaces to provide suction force to the substrate. A plurality of air holes is disposed in the plurality of holding surfaces to provide buoyancy force, opposite to the suction force, to the substrate. An interval adjusting unit adjusts an interval between the plurality of holding members to correspond to a size of a holding region extending from the plurality of holding surfaces to a size of the front surface of the substrate.

### CROSS-REFERENCE TO RELATED APPLICATION(S)

This application claims benefit of and priority to Korean Patent Application No. 10-2021-0134253, filed on Oct. 8, 2021 in the Korean Intellectual Property Office, the disclosure of which is incorporated by reference herein in its entirety.

### TECHNICAL FIELD

The present inventive concept relates to semiconductors and, more particularly, to a semiconductor substrate transfer apparatus and a method using the same.

### DISCUSSION OF THE RELATED ART

Semiconductors are getting smaller while they include more circuitry and so semiconductors are becoming more highly integrated. One way in which semiconductors can be more highly integrated is to perform a process called direct bonding in which one semiconductor die is bonded directly to the surface of another semiconductor die, without each semiconductor having to be independently packaged and wired. This process is known as direct bonding. In direct bonding, a bonding surface of a first semiconductor die and a second semiconductor die are plasma-treated, respectively, and the first semiconductor die is transferred and attached to the second semiconductor die. However, in a process of holding the first semiconductor die to be transferred, there may be a problem in that a plasma-treated surface of the first semiconductor die may become contaminated.

### SUMMARY

A substrate transfer apparatus, including a body unit including a plurality of modules. Each of the plurality of modules includes a plurality of holding surfaces for holding a front surface of a substrate. Each of the plurality of holding surfaces has one or more sides overlapping edges of the front surface of the substrate. A plurality of vacuum holes is disposed in the plurality of holding surfaces and forms negative pressure to provide suction force to the substrate. A plurality of air holes is disposed in the plurality of holding surfaces and form positive pressure to provide buoyancy force to the substrate. A driving unit adjusts an interval between each of the plurality of modules.

A substrate transfer apparatus includes a plurality of holding elements adjacent to a front surface of a substrate. The plurality of holding elements respectively includes a plurality of holding surfaces for holding the substrate. A plurality of vacuum holes is disposed in the plurality of holding surfaces to provide suction force to the substrate. A plurality of air holes is disposed in the plurality of holding surfaces to provide buoyancy force, opposite to the suction force, to the substrate. An interval adjusting unit adjusts an interval between each of the plurality of holding members to correspond to a size of a holding region extending from the plurality of holding surfaces to a size of the front surface of the substrate.

A substrate transfer apparatus includes a body unit including a plurality of modules. Each of the plurality of modules includes a plurality of holding surfaces for holding a front surface of a substrate. Each of the plurality of holding surfaces has one or more sides that overlap edges of the front surface of the substrate. A plurality of vacuum holes is disposed in the plurality of holding surfaces and provides suction force to the substrate. A plurality of air holes is disposed in the plurality of holding surfaces and provides buoyancy force, opposite to the suction force, to the substrate. A driving unit adjusts an interval between each of the plurality of modules. A camera unit captures an image of a front surface of the substrate. A control unit calculates a size of the front surface based on the image captured by the camera unit and adjusts the interval between each of the plurality of modules by the driving unit so that a size of a holding region extending from the plurality of holding surfaces corresponds to the size of the front surface.

### BRIEF DESCRIPTION OF DRAWINGS

The above and other aspects and features of the present inventive concept will be more clearly understood from the following detailed description, taken in conjunction with the accompanying drawings, in which:

FIG. 1 is a perspective view illustrating a substrate transfer apparatus according to an example embodiment of the present inventive concept;

FIG. 2 is a cross-sectional view taken in the direction I-I′ of FIG. 1;

FIG. 3A is a plan view viewed from a direction II of FIG. 2;

FIG. 3B is a plan view illustrating a state in which a module of the substrate transfer apparatus of FIG. 3A is moved toward a center of a body unit;

FIG. 4 is a view illustrating a state in which a substrate is held in the substrate transfer apparatus of FIG. 2;

FIG. 5 is a diagram illustrating a process in which the substrate held in the substrate transfer apparatus of FIG. 3 is restored to its original position

FIGS. 6 to 12 are modified examples of the substrate transfer apparatus of FIG. 2;

FIG. 13 is a perspective view illustrating a substrate transfer apparatus according to an example embodiment of the present inventive concept;

FIG. 14 is a block diagram of the substrate transfer apparatus of FIG. 13; and

FIG. 15 is a flowchart of a substrate transfer method according to an example embodiment of the present inventive concept.

### DETAILED DESCRIPTION

Hereinafter, example embodiments of the present inventive concept will be described with reference to the accompanying drawings.

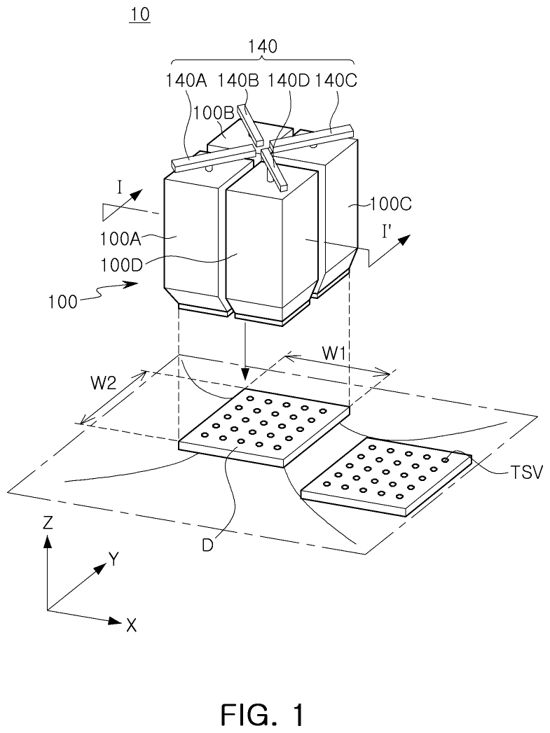

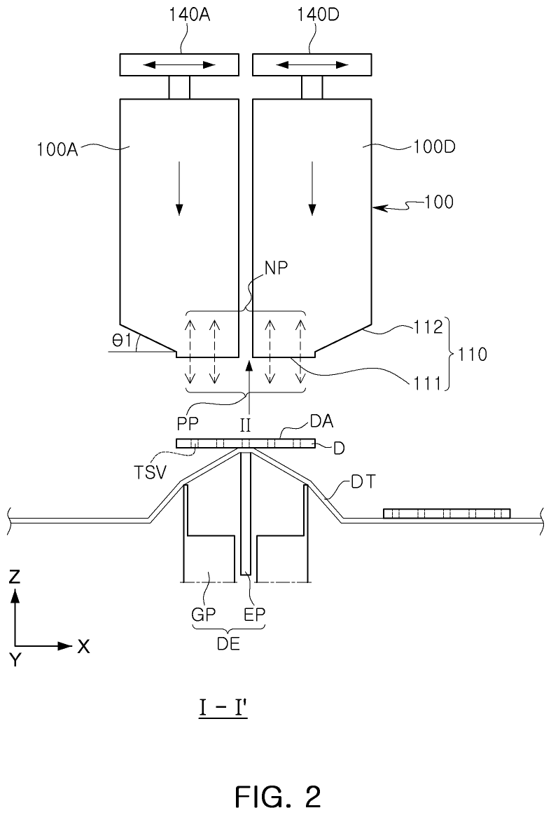

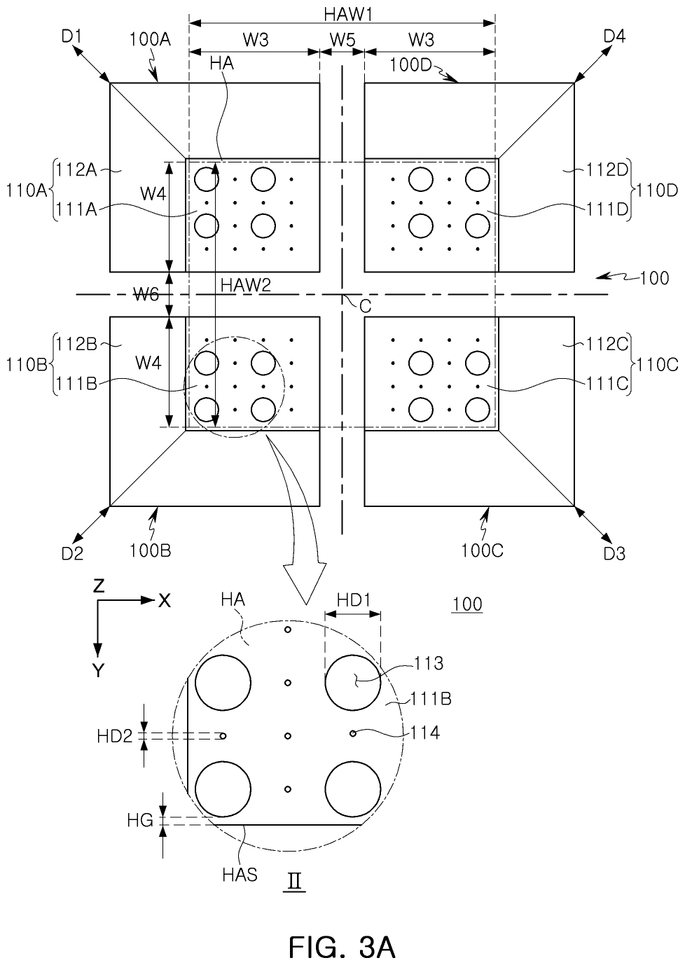

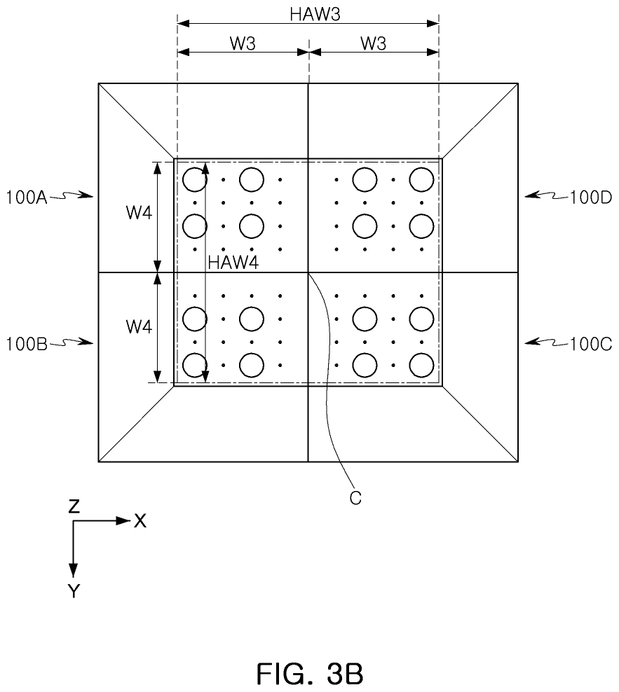

FIG. 1 is a perspective view illustrating a substrate transfer apparatus according to an example embodiment of the present inventive concept, and FIG. 2 is a cross-sectional view taken in the direction I-I′ of FIG. 1. FIG. 3A is a plan view viewed from the II direction of FIG. 2, and FIG. 3B is a plan view illustrating a state in which the module of the substrate transfer apparatus of FIG. 3A is moved.

Referring to FIGS. 1 and 2, a substrate transfer apparatus 10, according to an example embodiment of the present inventive concept, may be used to transfer a substrate D that is attached to a dicing tape DT. In an example embodiment, the substrate D may be a die in which a through silicon via (TSV) is formed. In addition, an upper surface DA of the substrate D may be plasma-treated for a subsequent process. The subsequent process may be a so-called direct bonding process in which the substrate D is directly bonded to a surface of a wafer. In the case of the example embodiment, a case in which the substrate D is of a square shape is described as an example, but the present inventive concept is not necessarily limited thereto, and the substrate D may have various other shapes such as a rectangle or a circle. In an example embodiment, the substrate D may have a square shape having a size of 10 mm×10 mm. In addition, the substrate D may have a thickness of 100 μm or less. According to example embodiments, the substrate D may have a thickness of 50 μm or more and 100 μm or less.

Referring to FIG. 2, the substrate D attached to an upper surface of the dicing tape DT is entirely lifted by a support unit GP of a die ejector DE disposed on a lower surface of the dicing tape DT, and most regions of the substrate D, excluding a central region in contact with the eject pin EP, may be separated from (e.g., spaced apart from) the dicing tape DT. The substrate transfer apparatus 10 may hold and transfer the substrate D separated from the dicing tape DT. When the upper surface DA of the substrate D is plasma-treated, the plasma-treated upper surface DA may be contaminated when the substrate transfer apparatus 10 directly holds the upper surface DA of the substrate D in contact therewith. In this case, in the process of bonding the substrate D to the wafer, a contact force of the substrate D may be weakened, and a void may be formed on a contact surface, resulting in a defect. The substrate transfer apparatus 10, according to an example embodiment, may perform holding without directly contacting the upper surface DA of the substrate D, so-called non-contact holding. Hereinafter, the substrate transfer apparatus 10 will be described in detail.

The substrate transfer apparatus 10 may have a body unit 100 and a driving unit 140. The body unit 100 may include a plurality of modules, and the driving unit 140 may adjust an interval between each of the plurality of modules.

The body unit 100 may have a structure in which modules 100A, 100B, 100C, and 100D having an approximately quadrangular pole shape are disposed adjacent to each other. However, the present inventive concept is not necessarily limited thereto, and a shape of the modules 100A, 100B, 100C, and 100D may be variously modified. The modules 100A, 100B, 100C, and 100D may be moved along a horizontal plane (X-Y plane) by the driving unit 140, and an interval therebetween can be adjusted. This will be described later in detail. In an example embodiment, a case in which the body unit 100 includes first to fourth modules 100A, 100B, 100C, and 100D will be described as an example. However, the present inventive concept is not necessarily limited thereto, and the body unit 100 may include two, three, or five or more modules.

The driving unit 140 may be disposed above the first to fourth modules 100A, 100B, 100C, and 100D, and may move the first to fourth modules 100A, 100B, 100C, and 100D outwardly from the central axis C of the body unit 100. In this case, the driving unit 140 may move the first to fourth modules 100A, 100B, 100C, and 100D at substantially the same speed. The driving unit 140 may include a plurality of driving units capable of linearly moving the first to fourth modules 100A, 100B, 100C, and 100D, respectively. In an example embodiment, the driving unit 140 will be described as an example in which the first to fourth driving units 140A, 140B, 140C, and 140D corresponding to the number of modules of the body unit 100 are included. However, the present inventive concept is not necessarily limited thereto, and one driving unit 140 may move all of the first to fourth modules 100A, 100B, 100C, and 100D. The driving unit 140 may linearly move the first to fourth modules 100A, 100B, 100C, and 100D outwardly from the central axis C of the body unit 100. For example, the driving unit 140 may include a linear stage.

Referring to FIGS. 2 and 3A, first to fourth holding surfaces 111A, 111B, 111C, and 111D directly facing the substrate D may be disposed on a lower surface 110 of each of the first to fourth modules 100A, 100B, 100C, and 100D constituting the body unit 100. The first to fourth holding surfaces 111A, 111B, 111C, and 111D may define a holding region HA having substantially the same size as an upper surface DA of the substrate D. The holding region HA is a region in which the substrate D is held without contact and refers to a region connecting the first to fourth holding surfaces 111A, 111B, 111C, and 111D. For example, the holding region HA refers to a region in which the first to fourth holding surfaces 111A, 111B, 111C, and 111D connect sides overlapping corners of the substrate D. Accordingly, the holding region HA may be variously deformed in terms of shape as the first to fourth modules 100A, 100B, 100C, and 100D move along a horizontal plane (X-Y plane) by the driving unit 140. The first to fourth holding surfaces 111A, 111B, 111C, and 111D may be symmetrically arranged with respect to a central axis C of the body unit 100 and may be formed to have the same size. The first to fourth holding surfaces 111A, 111B, 111C, and 111D may be positioned such that the holding region HA is disposed in a central region of a lower surface 110 of the body unit 100. A peripheral region 112 may be disposed around the first to fourth holding surfaces 111A, 111B, 111C, and 111D. The peripheral region 112 may include first to fourth peripheral regions 112A, 112B, 112C, and 112D. However, according to an example embodiment, the peripheral region 112 may be omitted.

The first to fourth holding surfaces 111A, 111B, 111C, and 111D may apply negative pressure (NP) (e.g., suction force) causing the substrate D to be completely separated from the dicing tape DT and move toward the body unit 100. In addition, the first to fourth holding surfaces 111A, 111B, 111C, and 111D may simultaneously provide positive pressure (PP) (e.g., buoyancy force) that prevents the substrate D to which the negative pressure NP is applied from directly contacting a surface of the body unit 100. The first to fourth holding surfaces 111A, 111B, 111C, and 111D may be configured to provide negative pressure and positive pressure having the same magnitude as each other.

Vacuum holes 113 providing the negative pressure NP and air holes 114 providing the positive pressure PP may be disposed on the first to fourth holding surfaces 111A, 111B, 111C, and 111D, respectively. The same number of vacuum holes 113 may be disposed in the first to fourth holding surfaces 111A, 111B, 111C, and 111D to provide the same negative pressure NP to the substrate D, respectively. In addition, the same number of air holes 114 may be disposed in the first to fourth holding surfaces 111A, 111B, 111C, and 111D to provide the same positive pressure PP to the substrate D, respectively. The vacuum holes 113 and the air holes 114 disposed on the first to fourth holding surfaces 111A, 111B, 111C and 111D may be symmetrical with respect to the central axis C of the body unit 100.

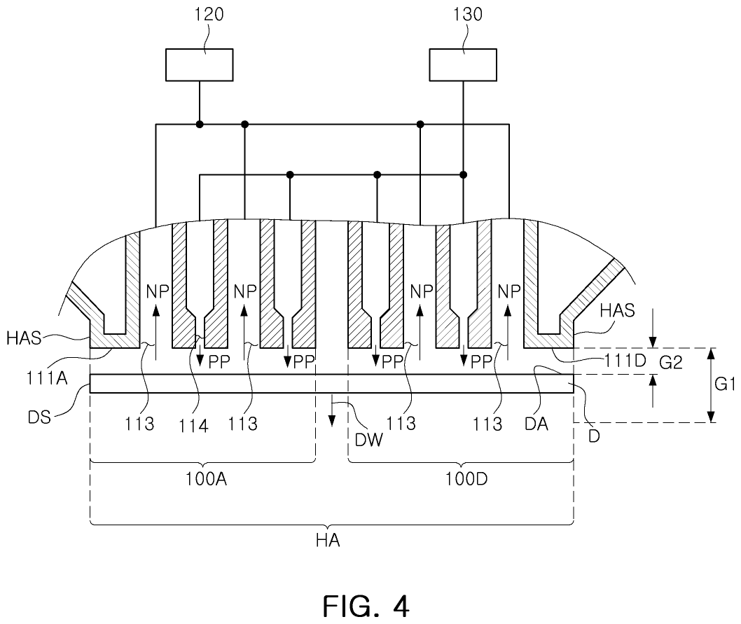

Referring to FIG. 4, the vacuum holes 113 may be connected to a vacuum source 120 and suck ambient air to form negative pressure NP around the vacuum holes 113. The first to fourth modules 100A, 100B, 100C, and 100D may be connected to the same vacuum source 120, to allow the vacuum holes 113 disposed in each of the first to fourth modules 100A, 100B, 100C, and 100D to form the same negative pressure (NP) with each other.

The vacuum holes 113 may provide negative pressure sufficient for the substrate D to be separated from the dicing tape DT and lifted toward the holding region HA. For example, the vacuum holes 113 may provide negative pressure NP sufficient to allow the substrate D to overcome a load DW and float in the air. An intensity of the negative pressure NP provided from the vacuum holes 113 may be adjusted so that an effective pressure reaches only a first distance G1, a predetermined distance, from the holding region HA. Accordingly, only when the body unit 100 is adjacent to the substrate D by a distance equal to or less than the first distance G1, the substrate D may be lifted. In an example embodiment, a magnitude of the negative pressure NP provided from the vacuum holes 113 may be appropriately adjusted according to a load DW of the substrate D.

Referring to FIG. 3A, each of the vacuum holes 113 may have a width HD1 of the same size. In addition, the vacuum holes 113 may be symmetrically disposed with respect to the central axis C of the holding region HA so that the negative pressure NP is not concentrated on a partial region of the holding region HA. In addition, the vacuum holes 113 may distributed at equal intervals so that the negative pressure is uniformly applied to the substrate D. The vacuum holes 113 may have a circular, elliptical, or polygonal shape or may have a shape of a long hole or trench. In the case of one embodiment, a case in which the vacuum holes 113 are formed in a circular shape has been described as an example.

Among the vacuum holes 113, the vacuum holes 113 disposed adjacent to each corner HAS of the holding region HA are for automatically aligning the substrate D with the holding region HA and may be in contact with each corner HAS of the holding region HA, but according to example embodiments, the vacuum holes 113 may be spaced apart from each corner HAS with a predetermined margin HG allowed in the process. Among the vacuum holes 113, the vacuum holes 113 disposed adjacent to each corner HAS of the holding region HA may serve to guide the substrate D lifted by the vacuum holes 113 to be disposed at a correct position exactly matched with the holding region HA.

Referring to FIGS. 3A and 4, the air holes 114 may be distributed and disposed at predetermined intervals on the holding surfaces 111A, 111B, 111C, and 111D. The air holes 114 may be connected to a compressed air source 130 to inject compressed air supplied from the compressed air source 130 to form positive pressure PP around the air holes 114. The first to fourth modules 100A, 100B, 100C, and 100D may be connected to the same compressed air source 130 and may allow the air holes 114 disposed in each of the first to fourth modules 100A, 100B, 100C, and 100D to form the same positive pressure PP as each other.

The positive pressure PP provided by the air holes 114 may provide buoyancy force so that the substrate D sucked to the holding region HA by the negative pressure NP of the vacuum holes 113 does not directly contact the holding region HA. For example, the air holes 114 may provide positive pressure PP acting in a direction opposite to the negative pressure NP of the vacuum holes 113. A width HD2 of the air holes 114 may be smaller than a width HD1 of the vacuum holes 113. In addition, the number of air holes 114 may be larger than the number of vacuum holes 113. The positive pressure PP supplied through the air holes 114 may be adjusted to act on a second distance G2 that is shorter than the first distance G1 by which the negative pressure NP supplied by the vacuum holes 113 acts. For example, a magnitude of the sum of the negative pressure NP provided by the vacuum holes 113 may be larger than a magnitude of the sum of the positive pressure PP provided by the air holes 114. Therefore, when the body unit 100 approaches the substrate D within the first distance G1, the negative pressure NP may act on the substrate D and the substrate D may be separated from the dicing tape DT and lifted. In addition, when the lifted substrate D approaches the body unit 100 within the second distance G2, the positive pressure PP may act on the substrate D, and the substrate D may be held in the holding region HA of body unit 100 without contact.

Referring to FIGS. 2 to 4, first to fourth peripheral regions 112A, 112B, 112C, and 112D may be disposed on at least one side of the first to fourth holding surfaces 111A, 111B, 111C, and 111D of the first to fourth modules 100A, 100B, 100C, and 100D. The first to fourth peripheral regions 112A, 112B, 112C, and 112D may be disposed on at least one side of each of the first to fourth holding surfaces 111A, 111B, 111C, and 111D to have a predetermined width. The first to fourth peripheral regions 112A, 112B, 112C, and 112D may be formed as inclined surfaces having a predetermined inclination angle θ1 with respect to the first to fourth holding surfaces 111A, 111B, 111C, and 111D. The first to fourth peripheral regions 112A, 112B, 112C, and 112D may be disposed around the holding region HA. The peripheral region 112 may be disposed around the holding region HA to prevent the negative pressure NP applied by the vacuum holes 113 and the positive pressure PP applied by the air holes 114 from being unintentionally affected by a surrounding air current.

A holding region HA will be described with reference to FIGS. 3A and 3B. FIG. 3A is a plan view illustrating a state in which the first to fourth modules 100A, 100B, 100C, and 100D of the substrate transfer apparatus 10 are spaced apart from each other. FIG. 3B is a plan view illustrating a state in which the first to fourth modules 100A, 100B, 100C, and 100D move toward the central axis C of the body unit 100 such that the first to fourth modules are in a dense state.

The holding region HA may have substantially the same shape and size to correspond to an upper surface of the substrate D. For example, when the substrate D has a rectangular shape, the holding region HA may also have a rectangular shape, and when the substrate D has a circular shape, the holding region HA may also have a circular shape. For example, when the substrate D is rectangular, a horizontal width HAW1 and a vertical width HAW2 of the holding region HA may have a size corresponding to a horizontal width W1 and a vertical width W2 of the substrate D illustrated in FIG. 1.

When the size of the holding region HA and the size of the substrate D are the same as each other, an effect of automatically aligning the substrate D with the holding region HA may be maximized. Accordingly, when the size of the substrate D is changed, the size of the holding region HA must also be changed correspondingly. However, when the body unit 100 is formed as a single body, in order to change the size of the holding region HA, the body unit 100 must be replaced, which may consume a lot of time. In the case of an example embodiment, since the size of the holding region HA can be changed by adjusting an interval between the modules of the body unit 100, the time consumed for changing the size of the holding region HA may be reduced.

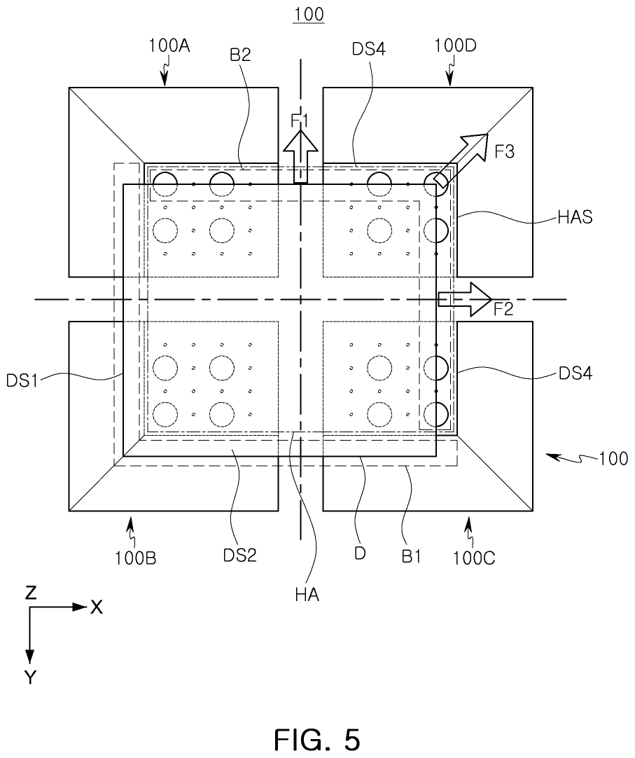

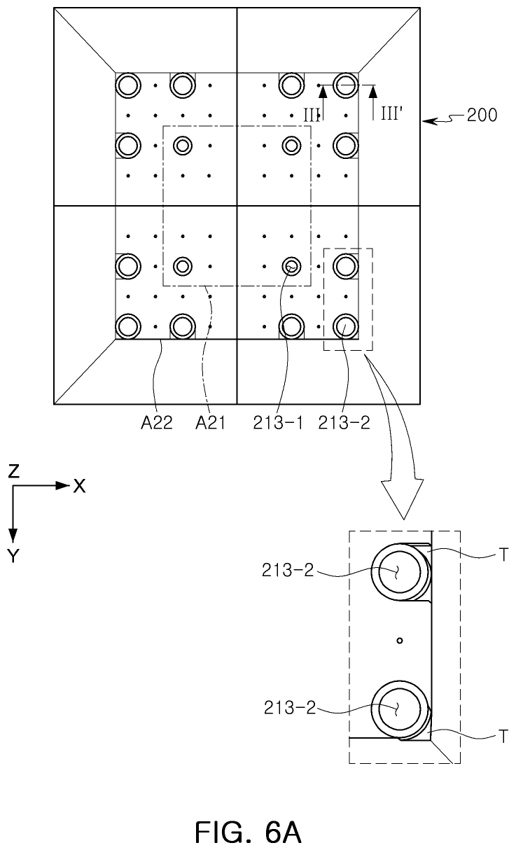

FIG. 5 is a view illustrating a process in which the substrate D is automatically aligned by a second vacuum hole 113B when the substrate D is not held in a correct position of the holding region HA.

In FIG. 5, if the substrate D is not accurately matched to the correct position of the holding region HA, so a partial region B1 of the substrate D protrudes externally of the holding region HA, the other partial region B2 is disposed to overlap the vacuum holes 113. In this case, atmospheric pressure is applied to a first side surface DS1 and a second side surface DS2 of the partial region B1. Negative pressure is applied to a third side surface DS3 and a fourth side surface DS4 of the other partial region B2. Accordingly, restoring forces F1 and F2 are applied to the third side surface DS3 and the fourth side surface DS4 of the substrate D in a direction to cancel the applied negative pressure. As a result, the substrate D may move in a direction of a resultant force F3 of the restoring forces F1 and F2 and may be positioned at the correct position in the holding region HA. Accordingly, the substrate D may be automatically aligned at a position exactly matched with the holding region HA.

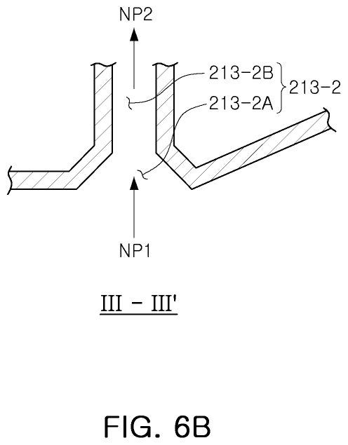

The shape and arrangement of the vacuum holes disposed on the first to fourth holding surfaces 111A, 111B, 111C, and 111D may be variously modified. Modified examples of the vacuum holes will be described with reference to FIGS. 6A to 6B.

Referring to FIGS. 6A to 6B, a width of first vacuum holes 213-1 disposed in a first region A21 positioned at a center of the holding region HA may be different from a width of second vacuum holes 213-2 disposed in a second region A22 positioned around the first region A21. For example, the width of the first vacuum holes 213-1 may be smaller than the width of the second vacuum holes 213-2.

In addition, a groove T stepped in the second vacuum holes 213-2 disposed adjacent to each corner of the holding region HA to have a level that is lower than a level of a surface of the holding region HA. The groove T formed in the second vacuum holes 213-2 may face the edge of the holding region HA. The groove T may serve as a passage through which air may flow into the second vacuum holes 213-2 even when the substrate is held above the second vacuum holes 213-2. Accordingly, the negative pressure applied to a vertex region of the substrate in which the substrate is held in the holding region HA may be reduced, compared to the region in which the groove T is not formed.

In addition, the first vacuum hole 213-1 and the second vacuum holes 213-2 may have a tapered cross-sectional shape, respectively. For example, as illustrated in FIG. 6B, an entrance region 213-2A of the second vacuum holes 213-2 may have a larger cross-sectional area than an internal region 213-2B. As the cross-sectional area of the vacuum hole increases, it may be difficult to uniformly maintain the negative pressure applied to the inside of the vacuum hole at a desired intensity. In an example embodiment, an internal negative pressure NP2B of the internal region 213-2B may be maintained at a desired intensity by forming the internal region 213-2B more adjacent to the vacuum source than the entrance region 213-2A, to be narrower. In addition, since the entrance region 213-2A is formed to have a larger cross-sectional area than the internal region 213-2B, a surface negative pressure NP1 having a magnitude smaller than that of the internal negative pressure NP2 may reach a wider region.

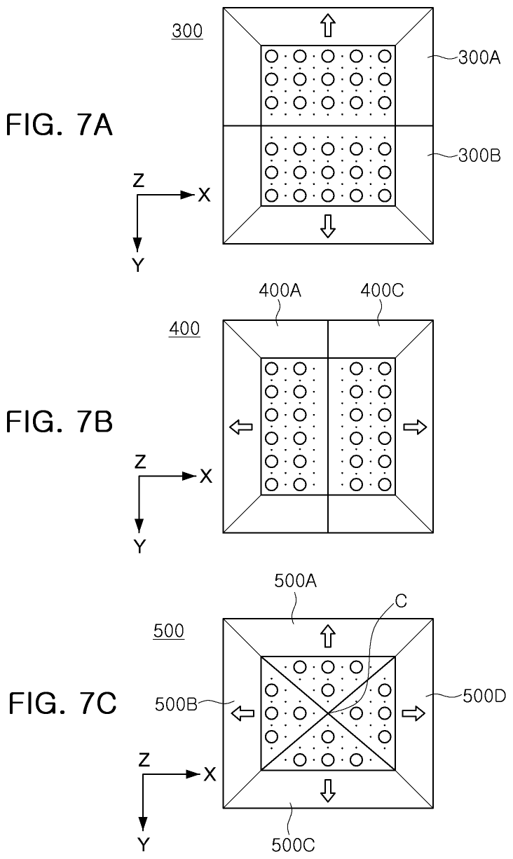

A shape and arrangement of the modules forming the holding region HA may be variously modified. A modified example of the substrate transfer apparatus will be described with reference to FIGS. 7A to 12. The same reference numerals as those described above may be understood as representing the same or a similar configuration and thus, to the extent that an element is not described in detail, it may be understood that the element is at least similar to a corresponding element that has been described in detail elsewhere within the instant specification.

FIGS. 7A to 7C illustrate examples in which modules respectively constituting a body unit of the substrate transfer apparatus, are symmetrically divided with respect to a central axis of the body unit.

FIG. 7A illustrates a case in which a body unit 300 includes first and second modules 300A and 300B, symmetrically divided with respect to an X-axis. The first and second modules 300A and 300B may move symmetrically in a Y-axis direction.

FIG. 7B illustrates a case in which a body unit 400 includes first and second modules 400A and 400B symmetrically divided with respect to a Y-axis. The first and second modules 400A and 400B may move symmetrically in an X-axis direction.

FIG. 7C illustrates an example in which a body unit 500 includes first to fourth modules 500A, 500B, 500C, and 500D moved in an X-axis direction and a Y-axis direction with respect to a central axis C of the body unit 500.

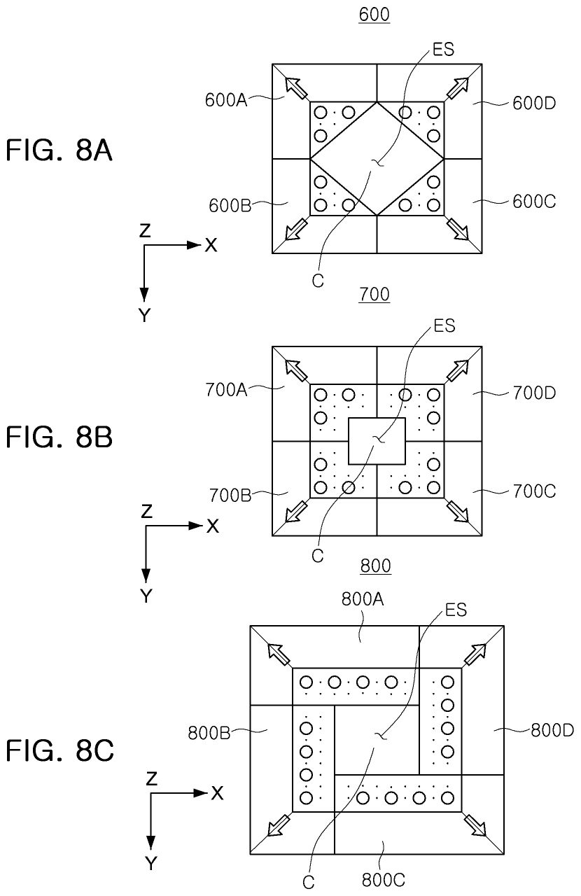

FIGS. 8A to 8C illustrate a case in which modules respectively constituting a body unit of the substrate transfer apparatus are symmetrically divided with respect to a central axis of the body unit, and an empty space ES is formed on the central axis of the body unit. The empty space ES disposed on the central axis of the body unit may be used as a space for disposing instruments other than the module. FIGS. 8A to 8C illustrate a case in which first to fourth modules move in an X-Y axis direction with respect to the empty space ES disposed on the central axis C of body units 600, 700, and 800, respectively.

The body unit 600 of FIG. 8A illustrates a case in which the body unit 600 of FIG. 8A includes first to fourth modules 600A, 600B, 600C, and 600D being moved symmetrically in an X-Y direction with respect to a central axis C.

The body unit 700 of FIG. 8B illustrates a case in which the body unit 700 of FIG. 8B includes first to fourth modules 700A, 700B, 700C, and 700D being moved symmetrically in an X-Y-axis direction with respect to a central axis C, and an empty space ES having a shape, different from that of FIG. 8A, is disposed on the central axis C.

The body unit 800 of FIG. 8C illustrates a case in which the body unit 800 of FIG. 8C includes first to fourth modules 800A, 800B, 800C, and 800D being moved symmetrically in an X-Y-axis direction with respect to a central axis C.

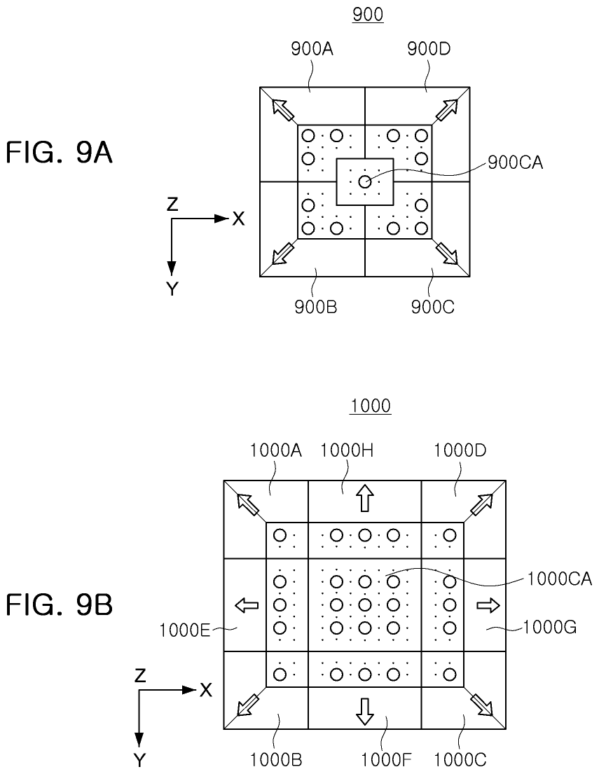

FIGS. 9A and 9B illustrate a case in which a module is added to a central axis of a body unit of the substrate transfer apparatus, respectively.

FIG. 9A illustrates a case in which a central module 900CA is disposed at a center of a body unit 900, and first to fourth modules 900A, 900B, 900C, and 900D are disposed around the central module 900CA. The central module 900CA may be fixed without moving, and the first to fourth modules 900A, 900B, 900C, and 900D may move symmetrically about the central module. When a size of a substrate held in the body unit increases, the central region of the substrate does not receive sufficient suction force, and thus a problem of downward sagging may occur. In an example embodiment, the central module 900CA may be added to the central axis of the body unit to provide additional suction force to the central region of the substrate.

FIG. 9B illustrates a case in which a central module 1000CA is disposed at a center of a body unit 1000, and first to eighth modules 1000A, 1000B, 1000C, 1000D, 1000E, 1000F, 1000G, and 1000H are disposed around the central module 1000CA.

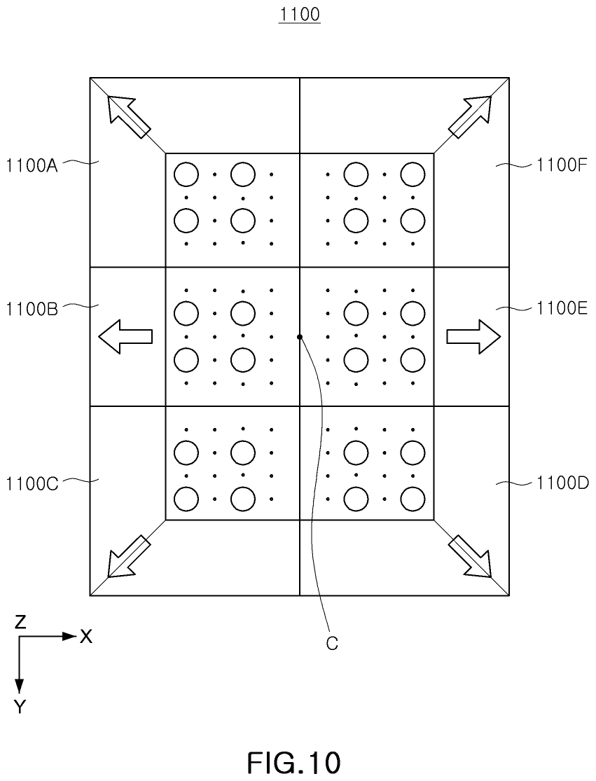

FIG. 10 illustrates a case in which a body unit 1100 includes first to sixth modules 1100A, 1100B, 1100C, 1100D, 1100E, and 1100F, and the first to sixth modules 1100A, 1100B, 1100C, 1100D, 1100E, and 1100F move radially with respect to a central axis C of the body unit 1100.

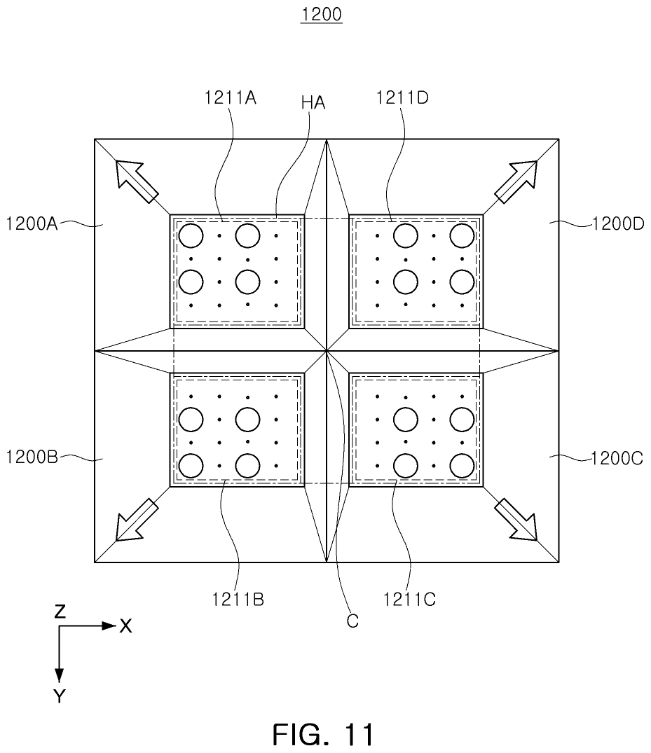

FIG. 11 illustrates a case in which a peripheral region is formed on each surface of holding surfaces 1211A, 1211B, 1211C, and 1211D respectively included in first to fourth modules 1200A, 1200B, 1200C, and 1200D included in a body unit 1200.

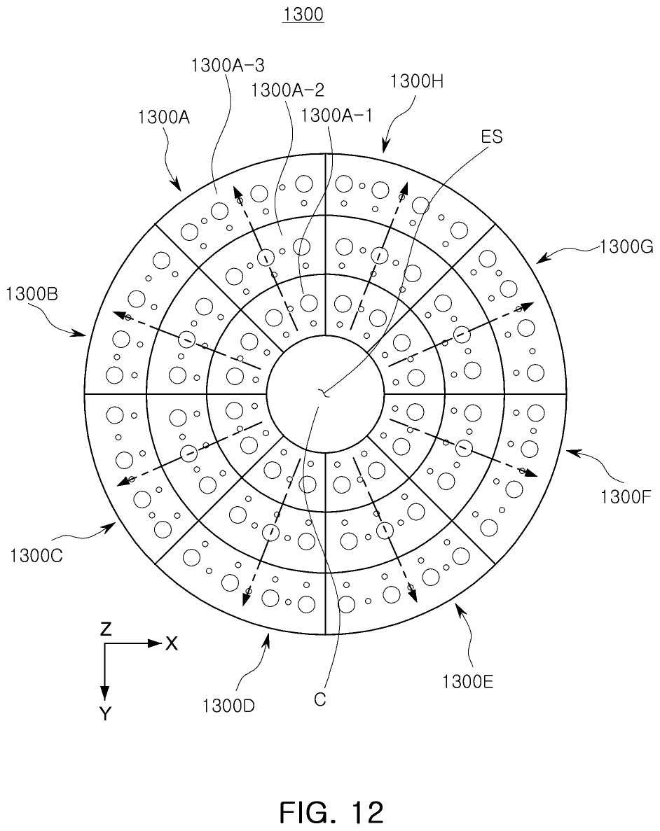

FIG. 12 illustrates a case in which a body unit 1300 of the substrate transfer apparatus holds a wafer without contact. A plurality of module arrays 1300A, 1300B, 1300C, 1300D, 1300E, 1300F, 1300G, and 1300H may be disposed radially from a central axis C of the body unit 1300, and each of the module arrays 1300A, 1300B, 1300C, 1300D, 1300E, 1300F, 1300G, and 1300H includes a plurality of modules. For example, the first module array 1300A may include first to third modules 1300A-1, 1300A-2, and 1300A-3. The plurality of module arrays 1300A, 1300B, 1300C, 1300D, 1300E, 1300F, 1300G, and 1300H and a plurality of modules included in the plurality of module arrays 1300A, 1300B, 1300C, 1300D, 1300E, 1300F, 1300G, and 1300H may move radially with respect to the central axis C, respectively. Accordingly, it is possible to hold wafers of various sizes without contacting the wafer. According to an example embodiment, an empty space ES may be disposed on the central axis C of the body unit 1300.

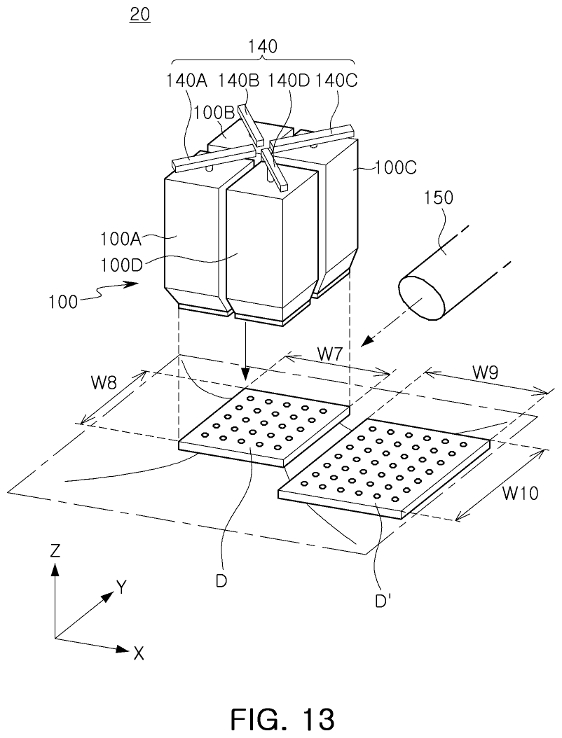

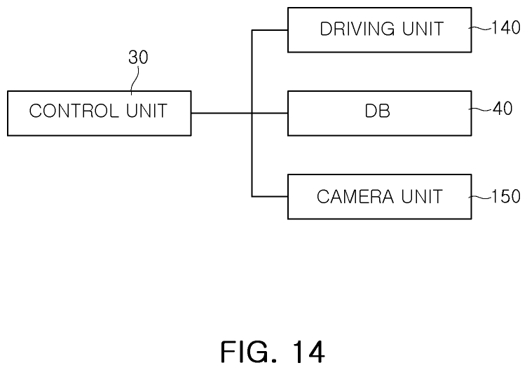

FIG. 13 is a perspective view schematically illustrating a substrate transfer apparatus 20 according to an example embodiment, and FIG. 14 is a block diagram of the substrate transfer apparatus 20 of FIG. 13. The same reference numerals as those described above may represent the same or similar elements and thus, to the extent that an element is not described in detail, it may be understood that the element is at least similar to a corresponding element that has been described in detail elsewhere within the instant specification.

Compared with the substrate transfer apparatus 10 of the above-described example embodiment, the substrate transfer apparatus 20 of an example embodiment has a difference in that a control unit 30, a database DB, and a camera unit 150 are further added.

The control unit 30 may entirely control the substrate transfer apparatus 20. The camera unit 150 may identify sizes W7 and W8 of the substrate D disposed below the body unit 100. A control value for controlling the driving unit 140 according to the size of the substrate may be previously stored in the database 40.

The substrate transfer apparatus 20 of an example embodiment may obtain an image of substrates D and D′ by the camera unit 150 and may control the driving unit 140 according to the size of the substrates D and D′, to adjust the size of the holding region HA of the body unit 100.

For example, the control unit 30 may obtain a first image of a first substrate D by the camera unit 150, and sizes W7 and W8 of the first substrate D may be identified based on the acquired first image. The control unit 30 may control the driving unit 140 based on the identified sizes W7 and W8 of the first substrate D to adjust an interval of the plurality of modules 100A, 100B, 100C, and 100D included in the body unit 100, and the first substrate D may be held. Subsequently, the control unit 30 may obtain a second image of a second substrate D′ by the camera unit 150, and sizes W9 and W10 of the second substrate D′ may be identified based on the obtained second image. The control unit 30 may control the driving unit 140 based on the identified sizes W9 and W10 of the second substrate D to adjust an interval of the plurality of modules 100A, 100B, 100C, and 100D included in the body unit 100, and the second substrate D′ may be held.

As described above, the substrate transfer apparatus 20 of an example embodiment may adjust the interval of the plurality of modules 100A, 100B, 100C, and 100D in real time according to the size of the substrates D and D′, so that the substrates of various sizes D and D′ may be held by one body unit 100.

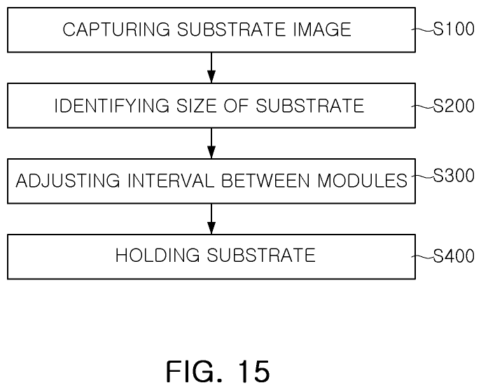

Next, a substrate transfer method according to an example embodiment will be described with reference to FIG. 15. The substrate transfer method according to an example embodiment may be performed using the substrate transfer apparatus 20 of FIG. 13 described above.

Referring to FIGS. 13 and 15, an image of the substrate D may be captured by the camera unit 150 (S100). The control unit 30 may identify a size of a front surface of the substrate D based on the captured image (S200). The control unit 30 may control the driving unit 140 based on the identified size of the substrate D to adjust an interval between the plurality of modules 100A, 100B, 100C, and 100D included in the body unit 100 (S300). The control unit 30 may adjust the interval of the plurality of modules 100A, 100B, 100C, and 100D so that a size of a holding region HA extending from each of holding surfaces included in the plurality of modules 100A, 100B, 100C, and 100D is the same as the size of the substrate D. Next, the body unit 100 may hold the substrate D without contact (S400).

As set forth above, since the substrate transfer apparatus according to the present inventive concept is configured to transfer the die by holding the die without contact, a surface of the die may be prevented from being contaminated by being in contact with the substrate transfer apparatus, and since the substrate transfer apparatus according to the present inventive concept is deformed so that a size of a die holding region corresponds to a size of a front surface of the die, dies of various sizes may be held in a non-contact state.

Various aspects and effects of the present inventive concept have been described above with reference to the drawings, however, it is to be understood that the invention is not necessarily limited to what has been described and depicted.

It will be apparent to those skilled in the art that modifications and variations could be made without departing from the scope of the present inventive concept.

What is claimed is:

1. A substrate transfer apparatus, comprising:
a body unit including a plurality of modules, wherein each of the plurality of modules includes a plurality of holding surfaces for holding a front surface of a substrate, wherein each of the plurality of holding surfaces has one or more sides overlapping edges of the front surface of the substrate;
a plurality of vacuum holes disposed in the plurality of holding surfaces and forming negative pressure to provide suction force to the substrate;
a plurality of air holes disposed in the plurality of holding surfaces and forming positive pressure to provide buoyancy force to the substrate; and
a driving unit for adjusting an interval between each of the plurality of modules.

2. The substrate transfer apparatus of claim 1, wherein each of the plurality of holding surfaces are disposed symmetrically with respect to a central axis of the body unit.

3. The substrate transfer apparatus of claim 2, wherein the body unit further comprises a central module having a holding surface that does not overlap the edges of the front surface in a region corresponding to the central axis of the body unit.

4. The substrate transfer apparatus of claim 2, wherein, in the body unit, a holding surface is not disposed in a region corresponding to the central axis of the body unit.

5. The substrate transfer apparatus of claim 1, wherein a magnitude of positive pressure provided by each of the plurality of holding surfaces is substantially equal to one another, and
a magnitude of negative pressure provided by each of the plurality of holding surfaces is substantially equal to one another.

6. The substrate transfer apparatus of claim 1, wherein the driving unit comprises a plurality of driving units respectively corresponding to the plurality of modules,
wherein each of the plurality of driving units moves a corresponding module of the plurality of modules with respect to a central axis of the body unit.

7. The substrate transfer apparatus of claim 6, wherein each of the plurality of driving units are spaced apart from each of the plurality of modules at equal intervals.

8. The substrate transfer apparatus of claim 7, wherein each of the plurality of driving units further comprises a linear stage for linearly moving the plurality of modules.

9. The substrate transfer apparatus of claim 1, wherein vacuum holes among the plurality of vacuum holes, adjacent to the one or more sides of the plurality of holding surfaces, have a stepped groove shape.

10. The substrate transfer apparatus of claim 1, wherein each of the plurality of air holes has a width that is narrower than that of each of the plurality of vacuum holes.

11. The substrate transfer apparatus of claim 1, wherein a number of the plurality of air holes is greater than a number of the plurality of vacuum holes.

12. The substrate transfer apparatus of claim 1, wherein a magnitude of a sum of positive pressure provided by each of the plurality of air holes is greater than a magnitude of a sum of negative pressure provided by each of the plurality of vacuum holes.

13. The substrate transfer apparatus of claim 1, wherein the substrate has a thickness of 100 μm or less.

14. A substrate transfer apparatus, comprising:
a plurality of holding elements adjacent to a front surface of a substrate, wherein the plurality of holding elements respectively includes a plurality of holding surfaces for holding the substrate;
a plurality of vacuum holes disposed in the plurality of holding surfaces to provide suction force to the substrate;
a plurality of air holes disposed in the plurality of holding surfaces to provide buoyancy force, opposite to the suction force, to the substrate; and
an interval adjusting unit for adjusting an interval between each of the plurality of holding elements to correspond to a size of a holding region extending from the plurality of holding surfaces to a size of the front surface of the substrate.

15. The substrate transfer apparatus of claim 14, wherein each of the plurality of holding surfaces comprise one or more sides that overlap edges of the front surface of the substrate.

16. The substrate transfer apparatus of claim 15, wherein the interval adjusting unit comprises a plurality of driving units respectively corresponding to the plurality of holding elements,
wherein each of the plurality of driving units moves a corresponding holding elements of the plurality of holding members with respect to a central axis passing through a center of the substrate.

17. The substrate transfer apparatus of claim 16, further comprising:
a camera unit for capturing an image of a front surface of the substrate; and
a control unit calculating a size of the front surface based on the image captured by the camera unit and adjusting an interval between each of the plurality of holding elements by the plurality of driving units so that a size of the holding region corresponds to the size of the front surface.

18. A substrate transfer apparatus, comprising:
a body unit including a plurality of modules, wherein each of the plurality of modules includes a plurality of holding surfaces for holding a front surface of a substrate, wherein each of the plurality of holding surfaces has one or more sides that overlap edges of the front surface of the substrate;
a plurality of vacuum holes disposed in the plurality of holding surfaces and providing suction force to the substrate;
a plurality of air holes disposed in the plurality of holding surfaces and providing buoyancy force, opposite to the suction force, to the substrate;
a driving unit for adjusting an interval between each of the plurality of modules;
a camera unit for capturing an image of a front surface of the substrate; and
a control unit for calculating a size of the front surface based on the image captured by the camera unit and adjusting the interval between each of the plurality of modules by the driving unit so that a size of a holding region extending from the plurality of holding surfaces corresponds to the size of the front surface.

19. The substrate transfer apparatus of claim 18, wherein the driving unit comprises a plurality of driving units respectively corresponding to the plurality of modules,
wherein the control unit drives the plurality of driving units, respectively, to symmetrically move the plurality of modules with respect to a central axis of the body unit.

20. The substrate transfer apparatus of claim 18, wherein each of the plurality of holding surfaces are disposed symmetrically with respect to a central axis of the body unit.
